(19) United States
(12) Patent Application Publication
(10) Pub. No.: US 2024/0145238 A1
(43) Pub. Date: May 2, 2024

(54) NANOSHEET WITH GRADED SILICON GERMANIUM LAYER UNDER ISOLATION REGION AND WITH BURIED TAPERED INNER SPACER

(71) Applicant: International Business Machines Corporation, Armonk, NY (US)

(72) Inventors: Reinaldo Vega, Mahopac, NY (US); Shogo Mochizuki, Mechanicville, NY (US); Ruilong Xie, Niskayuna, NY (US); Julien Frougier, Albany, NY (US); Ravikumar Ramachandran, Pleasantville, NY (US)

(21) Appl. No.: 18/050,554

(22) Filed: Oct. 28, 2022

(51) Int. Cl. H01L 21/02; H01L 29/06; H01L 29/423; H01L 29/66; H01L 29/775

(52) U.S. Cl. CPC H01L 21/0251; H01L 21/0245; H01L 21/02532; H01L 21/02603; H01L 29/0673; H01L 29/42392; H01L 29/66439; H01L 29/66545; H01L 29/66553; H01L 29/775

(57) ABSTRACT

Embodiments of the invention include an isolation layer under a nanosheet stack of a transistor and a graded layer under the isolation layer. The graded layer includes an impurity gradient.

### BACKGROUND

The present invention generally relates to fabrication methods and resulting structures for integrated circuits (ICs), and more specifically, to fabrication methods and resulting structures configured and arranged for providing nanosheets with a graded silicon germanium (SiGe) layer under an isolation region and with buried tapered inner spacers.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

While existing nanosheet transistors are suitable for their intended purposes, what is needed is further methods and resulting structures for nanosheet transistors which can prevent sub-sheet leakage according to one or more embodiments discussed herein.

### SUMMARY

Embodiments of the present invention are directed to providing fabrication methods and resulting structures for nanosheet transistors with a graded silicon germanium (SiGe) layer under an isolation region and with buried tapered inner spacers. A non-limiting method includes forming an isolation layer under a nanosheet stack of a transistor, and providing a graded layer under the isolation layer, the graded layer comprising a impurity gradient.

This can provide an improvement over known methods for a nanosheet transistor by providing regions that fully suppress sub-sheet current leakage from one source/drain region to another source/drain region under the gate. The graded layer under the isolation layer enhances critical thickness. Also, the graded layer results in a buried tapered inner spacer which can be used in implementations with a partial isolation layer.

In addition to one or more of the features described above or below, or as an alternative, further embodiments of the invention disclose wherein the graded layer comprises a tapered profile. This advantageously allows for the formation of buried tapered inner spacers to assist with suppressing current leakage from one source/drain region to another source/drain region under the gate. The graded layer can also assist with suppressing current leakage.

In addition to one or more of the features described above or below, or as an alternative, further embodiments of the invention disclose wherein the graded layer comprises a higher concentration of an impurity in the impurity gradient at a region nearest the isolation layer and comprises a lower concentration of the impurity at another region farthest away from the isolation layer. This advantageously allows for the formation of buried tapered inner spacers to assist with suppressing current leakage from one source/drain region to another source/drain region under the gate. The graded layer can also assist with suppressing current leakage.

In addition to one or more of the features described above or below, or as an alternative, further embodiments of the invention disclose wherein the graded layer comprises a tapered profile in correlation with an impurity concentration in the impurity gradient. This advantageously allows for the formation of buried tapered inner spacers to assist with suppressing current leakage from one source/drain region to another source/drain region under the gate. The graded layer can also assist with suppressing current leakage.

In addition to one or more of the features described above or below, or as an alternative, further embodiments of the invention disclose wherein at least a portion of a buried inner spacer layer extends under a gate region of the transistor. The buried inner space layer assists with suppressing current leakage from one source/drain region to another source/drain region under the gate.

In addition to one or more of the features described above or below, or as an alternative, further embodiments of the invention disclose wherein a buried inner spacer layer is adjacent to both the isolation layer and the graded layer. This advantageously allows for the buried inner spacer layer, the isolation layer, and the graded layer to assist with suppressing leakage from one source/drain region to another source/drain region under the gate.

In addition to one or more of the features described above or below, or as an alternative, further embodiments of the invention disclose wherein another isolation layer is under a source/drain region of the transistor, the another isolation layer being adjacent to the isolation layer and a buried inner spacer layer. This advantageously allows for the buried inner spacer layer, the isolation layer, and the other isolation layer to assist with suppressing leakage from one source/drain region to another source/drain region under the gate.

According to one of more embodiments of the invention, a non-limiting method includes forming an isolation layer under a nanosheet stack of a transistor, the transistor comprising a source/drain region. The method includes providing a graded layer under the isolation layer, the graded layer comprising an impurity gradient, wherein a sublayer is under the graded layer and adjacent to the source/drain region.

This can provide an improvement over known methods for a nanosheet transistor by providing regions that fully suppress sub-sheet current leakage from one source/drain region to another source/drain region under the gate. The graded layer under the isolation layer, if thick enough to result in stress relaxation, enhances the critical thickness of the sacrificial region used to form the isolation layer. Also, this results in a buried tapered inner spacer layer which can be used in implementations with a partial isolation layer. The isolation layer, graded layer, and sublayer assist with suppressing current leakage.

In addition to one or more of the features described above or below, or as an alternative, further embodiments of the invention disclose wherein the sublayer comprises a super steep retrograde well (SSRW) region. This advantageously allows for the SSRW region to prevent current leakage from one source/drain region to another source/drain region under the gate.

In addition to one or more of the features described above or below, or as an alternative, further embodiments of the invention disclose wherein the sublayer comprises silicon doped with carbon. This advantageously allows for the carbon-doped silicon material to prevent current leakage from one source/drain region to another source/drain region under the gate.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a top view of a portion of an integrated circuit (IC) under-fabrication after fabrication operations according to one or more embodiments of the invention;

FIG. 1B depicts a cross-sectional view of a portion of an IC under-fabrication after fabrication operations according to one or more embodiments of the invention;

FIG. 2 depicts a cross-sectional view of a portion of an IC under-fabrication after fabrication operations according to one or more embodiments of the invention;

FIG. 3 depicts a cross-sectional view of a portion of an IC under-fabrication after fabrication operations according to one or more embodiments of the invention;

FIG. 4 depicts a cross-sectional view of a portion of an IC under-fabrication after fabrication operations according to one or more embodiments of the invention;

FIG. 5 depicts a cross-sectional view of a portion of an IC under-fabrication after fabrication operations according to one or more embodiments of the invention;

FIG. 6 depicts a cross-sectional view of a portion of an IC under-fabrication after fabrication operations according to one or more embodiments of the invention;

FIG. 7 depicts a cross-sectional view of a portion of an IC under-fabrication after fabrication operations according to one or more embodiments of the invention;

FIG. 8 depicts a cross-sectional view of a portion of an IC under-fabrication after fabrication operations according to one or more embodiments of the invention;

FIG. 9 depicts a cross-sectional view of a portion of an IC under-fabrication after fabrication operations according to one or more embodiments of the invention;

FIG. 10 depicts a cross-sectional view of a portion of an IC under-fabrication after fabrication operations according to one or more embodiments of the invention;

FIG. 11 depicts a cross-sectional view of a portion of an IC under-fabrication after fabrication operations according to one or more embodiments of the invention;

FIG. 12 depicts a cross-sectional view of a portion of an IC under-fabrication after fabrication operations according to one or more embodiments of the invention;

FIG. 13 depicts a cross-sectional view of a portion of an IC under-fabrication after fabrication operations according to one or more embodiments of the invention;

FIG. 14 depicts a cross-sectional view of a portion of an IC under-fabrication after fabrication operations according to one or more embodiments of the invention;

FIG. 15 depicts a cross-sectional view of a portion of an IC under-fabrication after fabrication operations according to one or more embodiments of the invention;

FIG. 16 depicts a cross-sectional view of a portion of an IC under-fabrication after fabrication operations according to one or more embodiments of the invention;

FIG. 17 depicts a cross-sectional view of a portion of an IC under-fabrication after fabrication operations according to one or more embodiments of the invention;

FIG. 18 depicts a cross-sectional view of a portion of an IC under-fabrication after fabrication operations according to one or more embodiments of the invention;

FIG. 19 depicts a cross-sectional view of a portion of an IC under-fabrication after fabrication operations according to one or more embodiments of the invention;

FIG. 20 depicts a cross-sectional view of a portion of an IC under-fabrication after fabrication operations according to one or more embodiments of the invention;

FIG. 21 depicts a cross-sectional view of a portion of an IC under-fabrication after fabrication operations according to one or more embodiments of the invention;

FIG. 22 depicts a cross-sectional view of a portion of an IC under-fabrication after fabrication operations according to one or more embodiments of the invention;

FIG. 23 is a flowchart of a computer-implemented method of forming a nanosheet transistor with a graded layer and buried inner spacers according to one or more embodiments of the invention; and

FIG. 24 is a flowchart of a computer-implemented method of forming a nanosheet transistor with a graded layer and buried inner spacers according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

One or more embodiments disclose fabrication methods and resulting structures for providing nanosheet transistors with a graded SiGe layer under the isolation region and with buried tapered inner spacer layers. For a nanosheet transistor, a buried isolation layer is under a nanosheet stack but above a graded SiGe layer. A buried tapered inner sidewall spacer layer is adjacent to the graded SiGe layer, so as to be positioned under the isolation layer. The buried tapered inner sidewall spacer layer has a different maximum height and/or different maximum width than the inner spacers between the nanosheets. A super steep retrograde well (SSRW) region or a silicon doped with carbon region is under the graded SiGe layer, extending the full length of the nanosheet transistor.

In state-of-the-art transistors, the bottom dielectric isolation region in nanosheet FETs is relatively thin (e.g., approximately (˜) 10 nanometers (nm)), because of the critical thickness of the sacrificial silicon germanium layer (e.g., SiGe55 where germanium has an atomic percent (%) of about 55%) used to form the bottom dielectric isolation region. This leaves very little margin for source/drain recess etch and epitaxial pre-clean without punching through the bottom dielectric isolation region under the source/drain region. This can lead to sub-sheet leakage in the substrate because the source/drain junction directly contacts the substrate.

According to one or more embodiments of the invention, a method is provided for “re-isolating” the source/drain epitaxial regions from each other. Further, one or more embodiments of the invention includes a structure that enables a thicker isolation layer in general, thereby providing an increased margin for fin reveal etch on bulk nanosheet structures. One or more embodiments provide an arrangement for suppressing sub-sheet leakage in partial isolation layer configurations (having a shorter length) where the source/drain connects to the well/substrate.

According to one or more embodiments, the nanosheet transistor includes a graded SiGe region under the nanosheet structure which has a partial or full length isolation layer. The partial length isolation layer configuration can include a buried tapered inner spacer. The graded SiGe region is formed because it has a lateral SiGe etch rate that is dependent on the germanium percentage in the SiGe region, such that the gradation/gradients results in a tapered (or curved) partial release profile. The buried tapered inner spacer and SiGe region are utilized to suppress the sub-sheet leakage by blocking lateral junction. In one or more embodiments, a super steep retrograde well (SSRW) region or a silicon doped with carbon region can be utilized in the partial length isolation layer configuration to suppress sub-sheet leakage by using potential barrier and/or doping confinement.

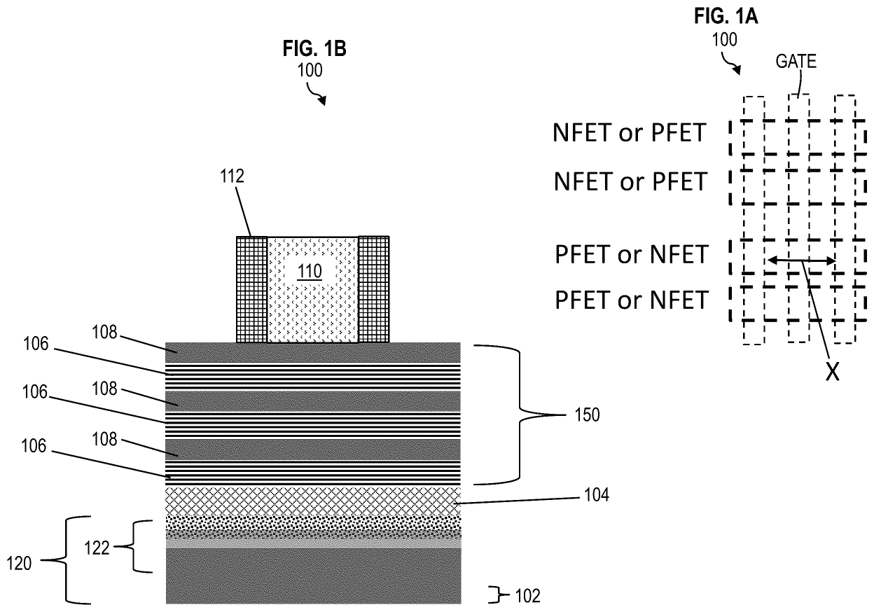

Turning now to a more detailed description of aspects of the present invention, FIG. 1A depicts a top view of a simplified illustration of a portion of an integrated circuit (IC) 100 and FIG. 1B depicts a cross-sectional view taken along X of the IC 100. For ease of understanding, some layers may be omitted from the top views so as not to obscure the figure. Although not necessarily formed at this stage, the top view represents nanosheet stacks as fins that are perpendicular to gates. As such, the top view is intended to provide a simplified illustration and a general orientation. Standard semiconductor fabrication techniques can be utilized to fabricate IC 100 as understood by one of ordinary skill in the art. Any suitable lithography processes including deposition techniques and etching techniques can be utilized herein.

FIG. 1B depicts the IC 100 after several fabrication processes have been performed. The IC 100 can start with a wafer or substrate 102 where a nanosheet stack 150 is formed on the substrate 102. The wafer or substrate 102 may be formed of silicon. Other suitable materials can be utilized for the substrate 102.

Graded silicon germanium (SiGe) epitaxial growth is performed by doping with graded concentrations of germanium (Ge) resulting in a graded/gradient SiGe layer and/or graded layer 122. The graded layer 122 has a lower concentration of germanium toward the bottom, with a higher concentration of germanium going toward the top, and resulting in the highest concentration of germanium at the top adjacent to an isolation layer 104. Accordingly, when epitaxially grown from the (silicon) substrate 102, the graded layer 122 has a gradient of germanium doped in the deposited material. To form the epitaxial graded layer 122, the germanium impurity concentration starts lower and continuously increases during the epitaxial growth. In one case, the germanium concentration can start from 0 atomic percent at the bottom of the SiGe graded layer 122 and reach a maximum of 30 atomic percent at the top. In another case, the germanium concentration can start from 0 atomic percent at the bottom of the SiGe graded layer 122 and reach a maximum of 55 atomic percent at the top. A combined layer or combined region 120 includes both the (silicon) substrate 102 and the graded layer 122. In one or more embodiments, ion implantation may be utilized to form the graded layer 122 with the gradient of germanium concentration.

Initially, the nanosheet stack 150 includes layers 106 formed in between layers 108. The layers 108 are semiconductor material and may be substantially pure silicon or any suitable materials. The layers 108 are to be utilized as the channel regions for the FET device. The layers 106 are sacrificial layers formed of silicon germanium (SiGe) where germanium has an atomic percent (%) of about 30%, thereby leaving silicon with an atomic percent of about 70%. In layers 106, the atomic percent of germanium may range from about 20-35%, while silicon is the remainder.

A first isolation layer 104 is formed between the nanosheet stack 150 and the substrate 102. Previously, a sacrificial layer (not shown) of silicon germanium was present (as a placeholder) that had a higher content of germanium than the layers 106, for example, the atomic percent of germanium may have been about 65-70%, while silicon is the remainder; as such, the sacrificial layer of silicon germanium (as the placeholder) was selectively etched, and deposition was performed to result in the formation of the first isolation layer 104. The first isolation layer 104 can be a low-k material or ultralow-k material.

It is noted that the highest atomic percent of germanium in the graded layer 122 is less than or equal to the atomic percent of germanium used in the sacrificial layer (not shown) of silicon germanium that was present (as a placeholder) for the first isolation layer 104. Further, the lowest concentration of germanium (at the bottom) of the graded layer 122 can have an atomic percent of 0% germanium (or nearly 0 atomic percent of germanium) leaving silicon as the remainder (e.g., 100 atomic percent silicon), while the highest concentration of germanium (at the top) of the graded layer 122 can have an atomic percent of germanium that ranges from about 50-65% leaving silicon as the remainder, such that a gradient of germanium is present that increases in germanium concentration from the bottom to top. As discussed further herein, the gradient of germanium in the SiGe material of the graded layer 122 directly affects the etch rate of different portions of the graded layer 122, such that portions of the graded layer 122 having a higher concentration of germanium are etched faster than portions of the graded layer 122 having a lower concentration of germanium, with portions having no germanium being unaffected or nearly unaffected.

Low-k dielectric materials may generally include dielectric materials having a k value of about 5.9 or less, such as silicon dioxide. The ultralow-k dielectric material generally includes dielectric materials having a k value less than 2.5. Unless otherwise noted, all k values mentioned in the present application are measured relative to a vacuum. Exemplary ultralow k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultralow-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low k dielectric films can be formed by hydrolysis and polycondensation of an alkoxide(s) such as tetraetehoxysilane (TEOS).

A dummy gate 110 is formed and patterned using standard processing. The dummy gate 110 is sacrificial in nature in that it is replaced at a later point in the process flow with other materials to form functional gate structures, as described below. The dummy gate 110 may include one or more layers of material, such a sacrificial gate material (e.g., amorphous silicon or polysilicon). Gate spacers 112 are formed on the sidewalls of the dummy gate 110. The gate spacers 112 may include a dielectric such as a nitride, oxide, oxynitride, etc.

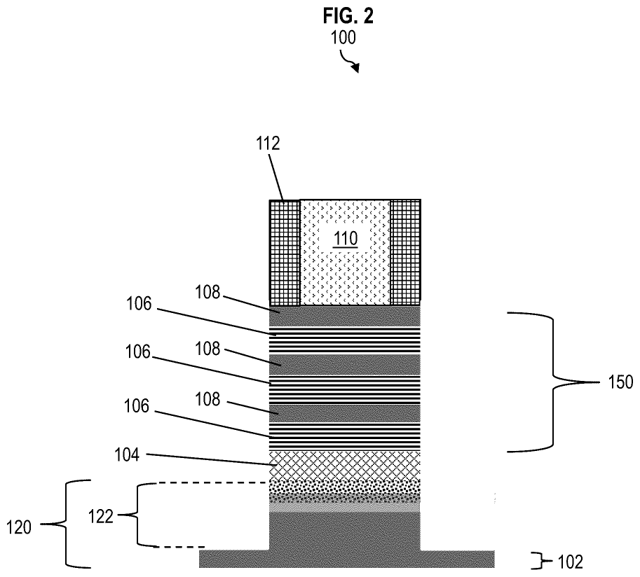

FIG. 2 depicts the IC 100 after etching in preparation for source/drain formation. For example, using a patterned hard mask layer (not shown), fin patterning is performed to form the nanosheet stack 150 into fins, which may extend below the first isolation layer 104 and the graded layer 122. The etching continues into portions of the substrate 102 in preparation for source/drain formation.

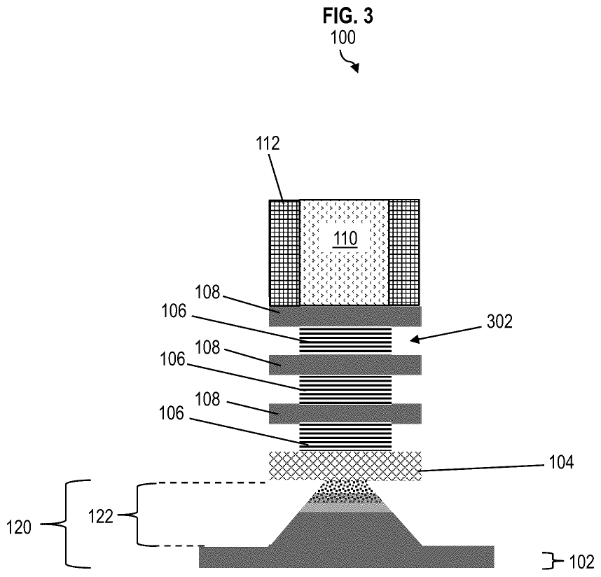

FIG. 3 depicts the IC 100 after etching in preparation for inner spacer formation. An etch is performed to selectively remove portions of the layers 106. For example, an isotropic etch process is performed to selectively recess the layers 106 in order to define end cavities 302 on ends thereof. Also, this etching simultaneously etches the combined region 120 where upper portions of the graded layer 122 near the isolation layer 104 are etched at a faster rate than the lower portions of the graded layer 122 nearing the substrate 102. The lowest portion of the graded layer 122 may be pure silicon with 0% germanium. The etching results in a tapered profile, a triangular shape, and/or a pyramid shape for the graded layer 122, based on the atomic percent of germanium present in the gradient of germanium. The higher the content of germanium, the greater the etch rate. A wet etch or dry etch may be utilized to etch the silicon germanium. An example etchant may include acetic acid, hydrogen peroxide, and/or hydrofluoric acid.

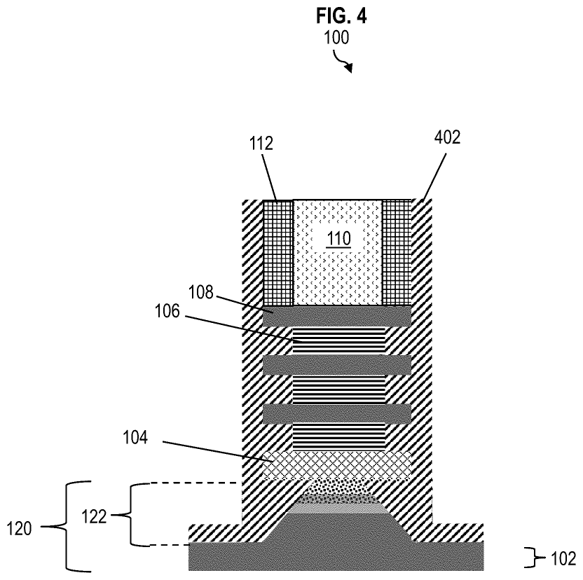

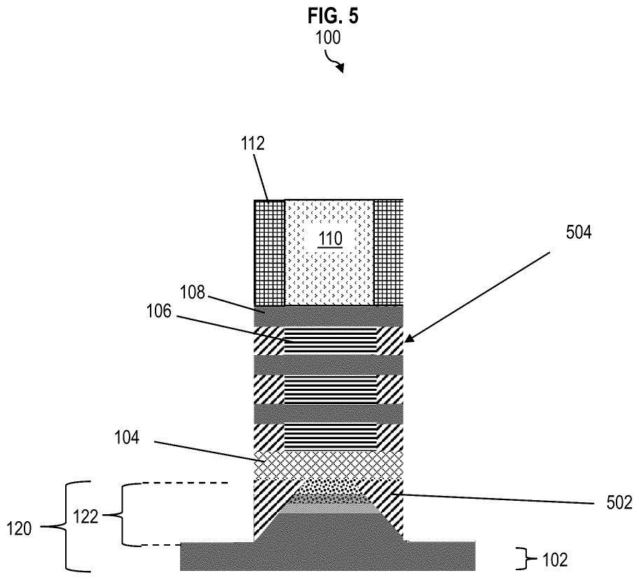

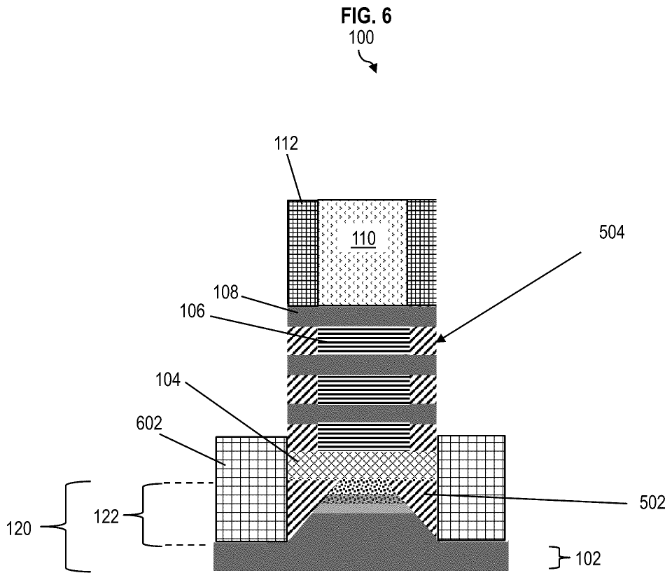

FIG. 4 depicts the IC 100 after the deposition of inner spacer material. A conformal deposition process, such as an ALD process, is performed to form a layer of inner spacer material 402 on the nanosheet stack 150, and the inner spacer material 402 is anisotropically etched. A wet etch or a dry etch may be utilized. As an example dry etch, a RIE etch can be utilized. As an example wet etch, a dilute phosphoric acid can be utilized. Example materials of the inner spacer material 402 may include SiBCN, SiOCN, SiN, SiOC, SiC, etc. The inner spacer material 402 can be a nitride with oxygen, carbon, and/or boron added. In one example, the inner spacer material 402 may include silicon dioxide. The inner spacer material 402, which is utilized to form a buried tapered inner sidewall spacers 502 (depicted in FIG. 5), is a different material from the first isolation layer 104, as well as the second isolation layer 602 (depicted in FIG. 6).

FIG. 5 depicts the IC 100 after the inner spacer etch back. An isotropic etch can be utilized to selectively etch the inner spacer material 402 as previously discussed herein, thereby resulting in inner spacers 504 in the cavities 302 (depicted in FIG. 3). Concurrently, the etching can be performed to define buried tapered inner sidewall spacers 502 on the sidewalls of the graded layer 122, sidewalls of portions of the substrate 102, and sidewalls of portions of the combined region 120. A wet etch or a dry etch may be utilized. As an example dry etch, a RIE etch can be utilized. As an example wet etch, a dilute phosphoric acid can be utilized.

FIG. 6 depicts the IC 100 after a dielectric fill and recess. A dielectric material is deposited and recessed to form a second isolation layer 602. The second isolation layer 602 is in contact with both the first isolation layer 104 and the buried tapered inner sidewall spacers 502. The second isolation layer 602 can be an oxide, for example, silicon dioxide, germanium oxide, aluminum oxide, etc. The second isolation layer 602 is a different material from the first isolation layer 104, such that the material of the second isolation layer 602 can be selectively etched without etching the first isolation layer 104. A dry or wet etch may be utilized to recess the dielectric material of the second isolation layer 602. In one example, a dilute HCl acid can be utilized.

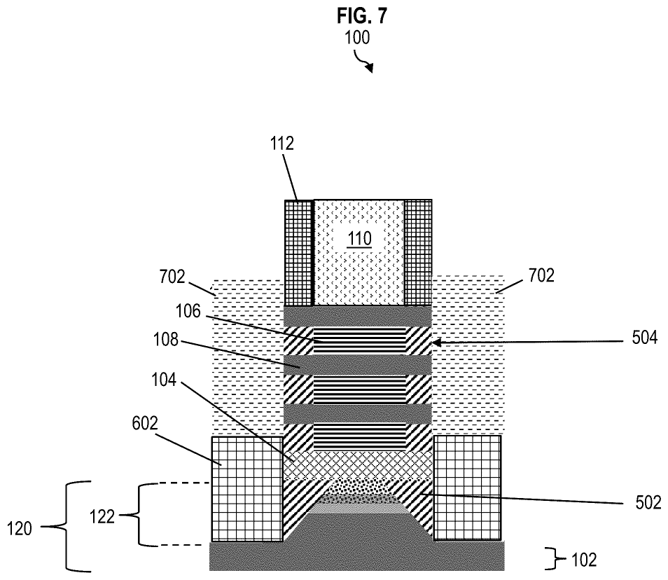

FIG. 7 depicts the IC 100 after source and drain formation. The epitaxial layers 702 are epitaxially grown from the layers 108. For P-type FETs (PFETs), the epitaxial layers 702 may be doped to be P-type epitaxial material, resulting in P-type source and drain regions. For N-type FETs (NFETs), the epitaxial layers 702 may be doped to be N-type epitaxial material, resulting in N-type source and drain regions. The epitaxial layers 702 sits directly on the second isolation layers 602. In one or more embodiments, the source/drain regions can be a deposited metal and may not be epitaxially grown.

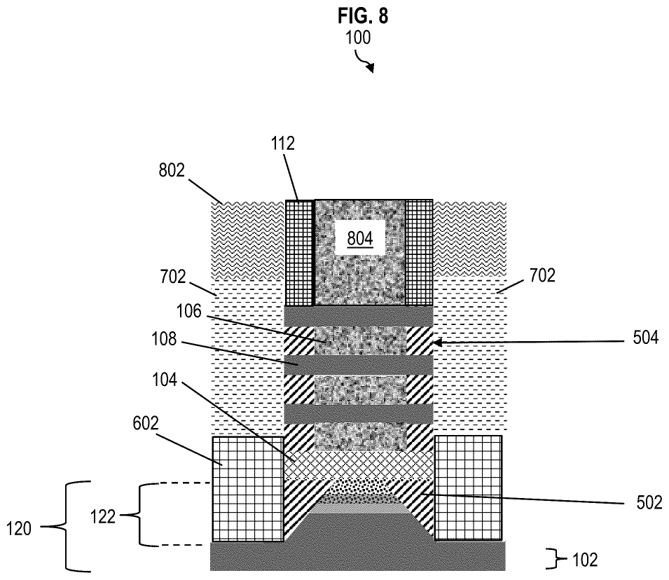

FIG. 8 depicts the IC 100 after dummy gate removal. The dummy gate 110 is removed, and the sacrificial layers 106 (SiGe) are released. Replacement metal gate (RMG) formation is performed, thereby forming a gate structure 804. The replacement metal gate process is performed to deposit a high-k dielectric material followed by one or more work function material layers to thereby form the gate structure 804. An interlayer dielectric (ILD) material 802 may be formed. The ILD material 802 can be a low-k dielectric material or an ultralow-low k dielectric material. Although not shown, cavities can be formed in the ILD material 802 and a metal can be deposited to fill the cavities, thereby forming the source/drain metal contacts. A portion of the source/drain metal contacts may include silicide, resulting from the interface of the metal material and semiconductor material.

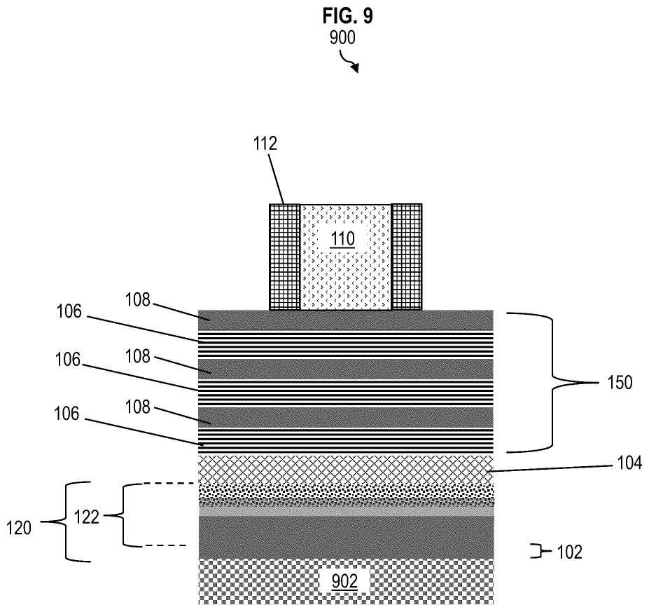

According to one or more embodiments, FIG. 9 depicts another example of an IC 900. FIG. 9 illustrates a graded SiGe layer under the nanosheet with buried tapered inner spacers and a sublayer 902 that directly contacts the source/drain regions. Some of the description for the IC 900 is analogous to the IC 100 with minor modifications. Accordingly, the fabrication processes previously discussed are not repeated.

As seen in FIG. 9, a sublayer 902 is formed under the substrate 102. In one or more embodiments, the sublayer 902 can be a silicon doped with carbon layer. In this case, the silicon can be doped with carbon of about 2 atomic percent (%) or less. In one example, the carbon in silicon carbon layer could be about 1 atomic percent, with silicon as the remainder.

In one or more embodiments, the sublayer 902 can be a super steep retrograde well (SSRW) layer. Any suitable technique can be utilized to form the SSRW layer as understood by one of ordinary skill in the art. In one case, the SSRW layer can have a low-high-low channel doping profile or a low-high channel doping profile, which can improve the control of short-channel effect (SCE) without degrading mobility. For example, the SSRW has a highly doped region adjacent to a non-doped region, thereby forming a PN junction or an NP junction. The dopants can include boron for N-type dopants and phosphorous (along with carbon) for P-type dopants. Other suitable dopants can be utilized in the epitaxial growth of the SSRW layer.

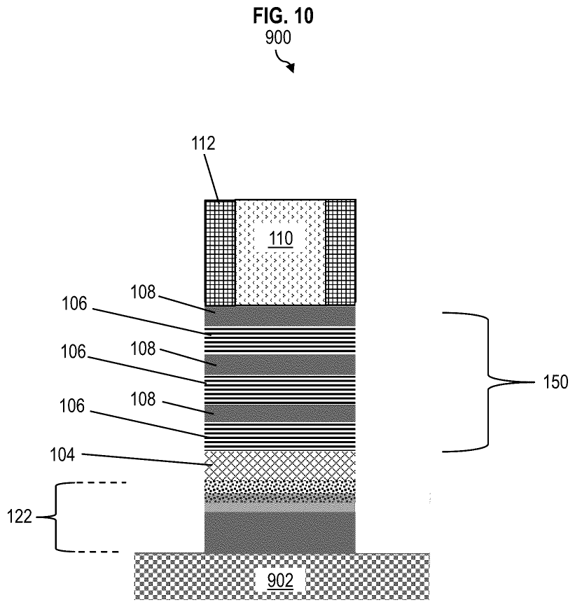

FIG. 10 depicts the IC 900 after etching in preparation for source/drain formation. For example, using a patterned hard mask layer (not shown), fin patterning is performed to form the nanosheet stack 150 into fins, which also punches through the graded layer 122, stopping on the sublayer 902. Unlike, the IC 100, etching continues until the sublayer 902 is exposed. RIE etching may be utilized.

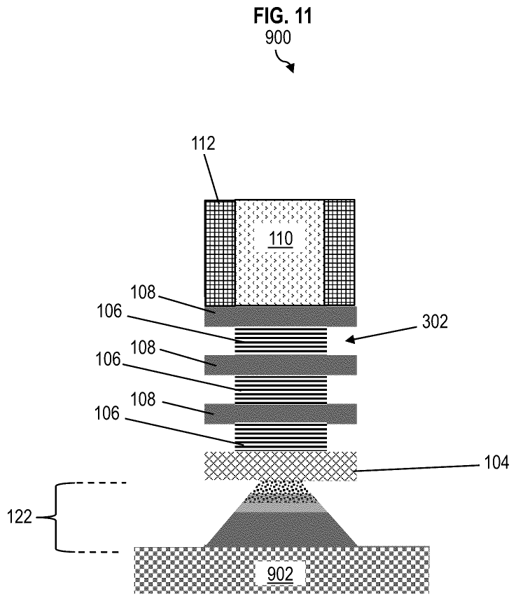

FIG. 11 depicts the IC 900 after etching in preparation for inner spacer formation. An etch is performed to selectively remove portions of the layers 106. For example, an isotropic etch process is performed to selectively recess the layers 106 in order to define end cavities 302 on ends thereof. The etching results in a tapered profile, a triangular shape, and/or a pyramid shape for the graded layer 122, based on the atomic percent of germanium present in the gradient of germanium. The higher the content of germanium, the greater the etch rate. A wet etch or dry etch may be utilized to etch the silicon germanium. An example etchant may include acetic acid, hydrogen peroxide, and/or hydrofluoric acid.

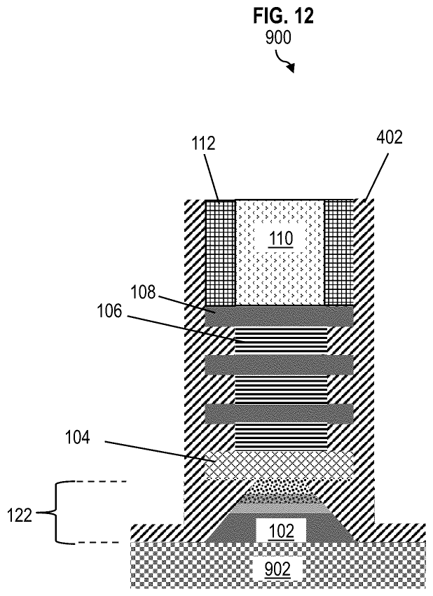

FIG. 12 depicts the IC 900 after deposition of inner spacer material. A conformal deposition process, such as an ALD process, is performed to form a layer of inner spacer material 402 on the nanosheet stack 150, the graded layer 122, and the sublayer 902. The inner spacer material 402 is anisotropically etched (e.g., RIE). Example materials of the inner spacer material 402 may include SiBCN, SiOCN, SiN, SiOC, SiC, etc. The inner spacer material 402 can be a nitride with oxygen, carbon, and/or boron added. In one example, the inner spacer material 402 may include silicon dioxide. Again, the inner spacer material 402 is utilized to form the buried tapered inner sidewall spacers 502, which is a different material from the first isolation layer 104.

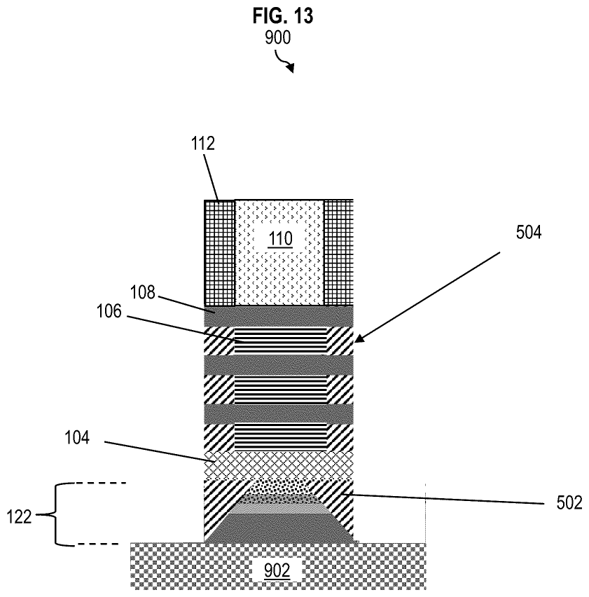

FIG. 13 depicts the IC 900 after the inner spacer etch back. An isotropic etch can be utilized to selectively etch the inner spacer material 402 as previously discussed herein, thereby resulting in inner spacers 504 in the cavities 302 (depicted in FIG. 3). Concurrently, the etching can be performed to define buried tapered inner sidewall spacers 502 on the sidewalls of the graded layer 122, on sidewalls of portions of the substrate 102 (if present), and sidewalls of portions of the combined region 120. A wet etch or a dry etch may be utilized. In one or more embodiments, a bottom portion of the buried tapered inner sidewall spacers 502 can contact the sublayer 902 underneath. In one or more embodiments, a bottom portion of the buried tapered inner sidewall spacers 502 may not contact the sublayer 902 underneath because a lowest portion of the graded layer 122 was not etched and/or because the substrate is present. As an example dry etch, a RIE etch can be utilized. As an example wet etch, a dilute phosphoric acid can be utilized.

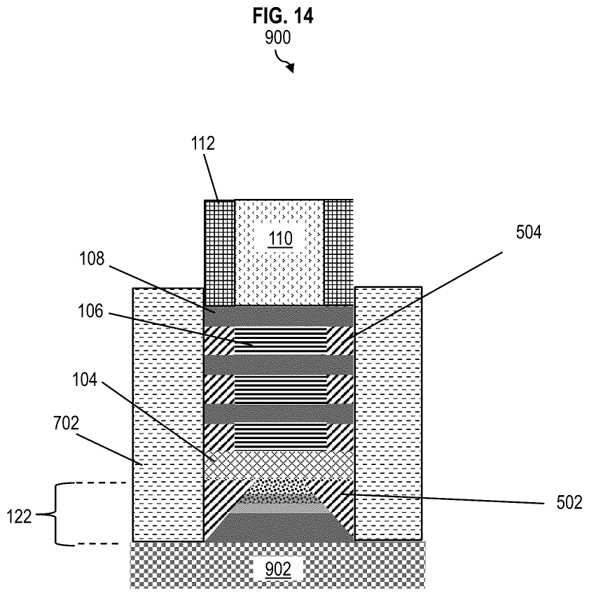

FIG. 14 depicts the IC 900 after source and drain formation. The epitaxial layers 702 are epitaxially grown from the layers 108. For P-type FETs (PFETs), the epitaxial layers 702 may be doped to be P-type epitaxial material, resulting in P-type source and drain regions. For N-type FETs (NFETs), the epitaxial layers 702 may be doped to be N-type epitaxial material, resulting in N-type source and drain regions. The epitaxial layers 702 sit directly on the sublayer 902. As noted above, the source/drain regions could be a conductive material or metal that is not epitaxially grown.

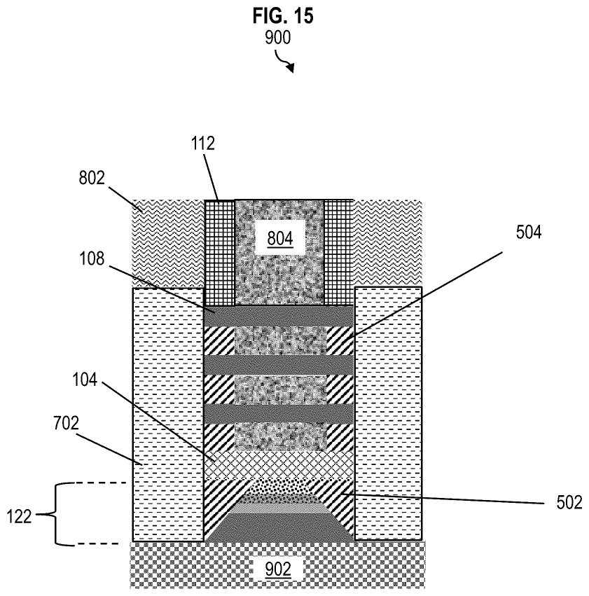

FIG. 15 depicts the IC 900 after dummy gate removal. The dummy gate 110 is removed, and the sacrificial layers 106 (SiGe) are released. Replacement metal gate (RMG) formation is performed, thereby forming a gate structure 804. The replacement metal gate process is performed to deposit a high-k dielectric material followed by one or more work function material layers to thereby form the gate structure 804. An interlayer dielectric (ILD) material 802 may be formed. The ILD material 802 can be a low-k dielectric material or an ultralow-low k dielectric material. Although not shown, cavities can be formed in the ILD material 802 and a metal can be deposited to fill the cavities, thereby forming the source/drain metal contacts. A portion of the source/drain metal contacts may include silicide, resulting from the interface of the metal material and semiconductor material.

Although the sublayer 902 could be separated from the graded layer 122 by some portion of the substrate, as in FIG. 9, in one or more embodiments, as in FIGS. 10-15, the portion of the substrate is not present, and the graded layer 122 is in direct contact with the sublayer 902 (i.e., no substrate separation).

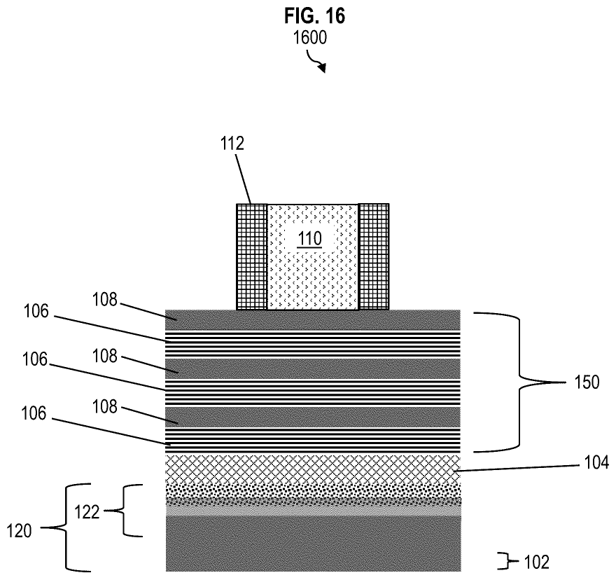

According to one or more embodiments, FIG. 16 depicts an IC 1600 with a full isolation layer 104. Some of the description for the IC 1600 is analogous to the IC 100 with minor modifications. Accordingly, the fabrication processes previously discussed are not repeated. The IC 1600 includes the graded layer 122 as discussed herein.

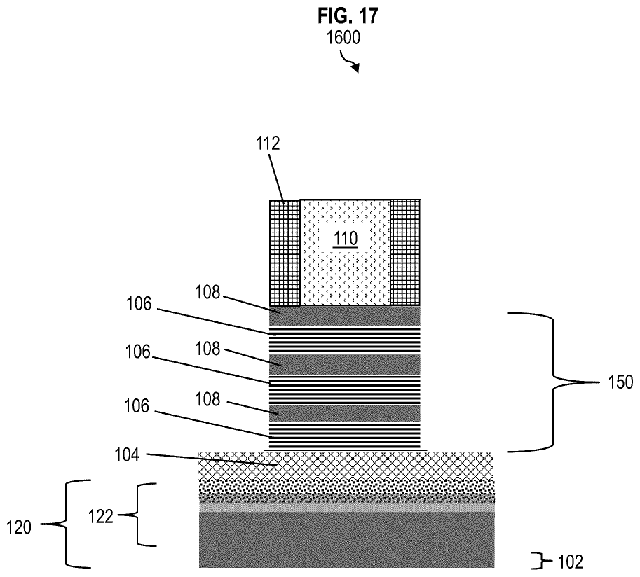

FIG. 17 depicts the IC 1600 after etching in preparation for source/drain formation. For example, using a patterned hard mask layer (not shown), fin patterning is performed to form the nanosheet stack 150 into fins. The etching stops on the first isolation layer 104, unlike the IC 100 and the IC 900. Accordingly, the isolation layer 104 has a full length or width.

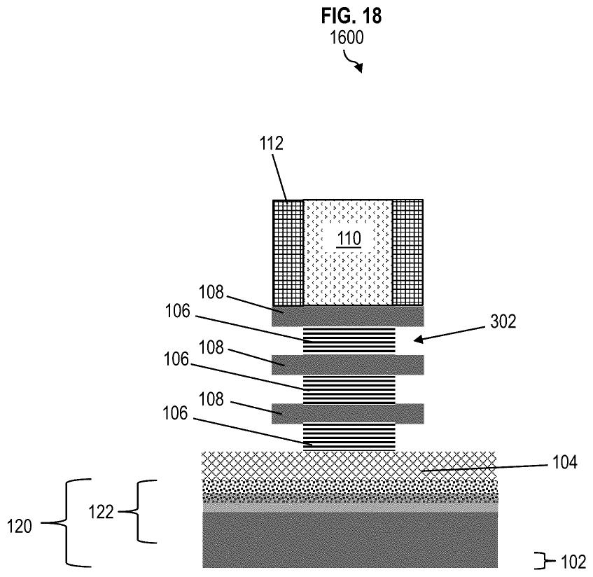

FIG. 18 depicts the IC 1600 after etching in preparation for inner spacer formation. An etch is performed to selectively remove portions of the layers 106. For example, an isotropic etch process is performed to selectively recess the layers 106 in order to define end cavities 302 on ends thereof. A wet etch or dry etch may be utilized to etch the silicon germanium. An example etchant may include acetic acid, hydrogen peroxide, and/or hydrofluoric acid.

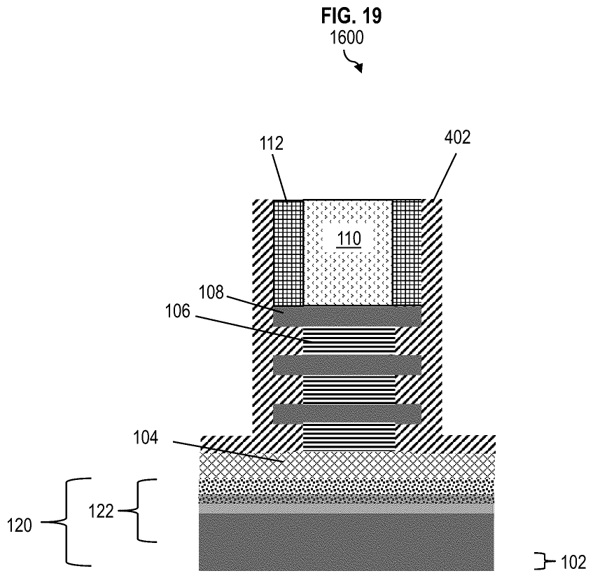

FIG. 19 depicts the IC 1600 after the deposition of inner spacer material. A conformal deposition process, such as an ALD process, is performed to form a layer of inner spacer material 402 on the nanosheet stack 150, and the inner spacer material 402 is anisotropically etched. Example materials of the inner spacer material 402 may include SiBCN, SiOCN, SiN, SiOC, SiC, etc. The inner spacer material 402 can be a nitride with oxygen, carbon, and/or boron added. In one example, the inner spacer material 402 may include silicon dioxide.

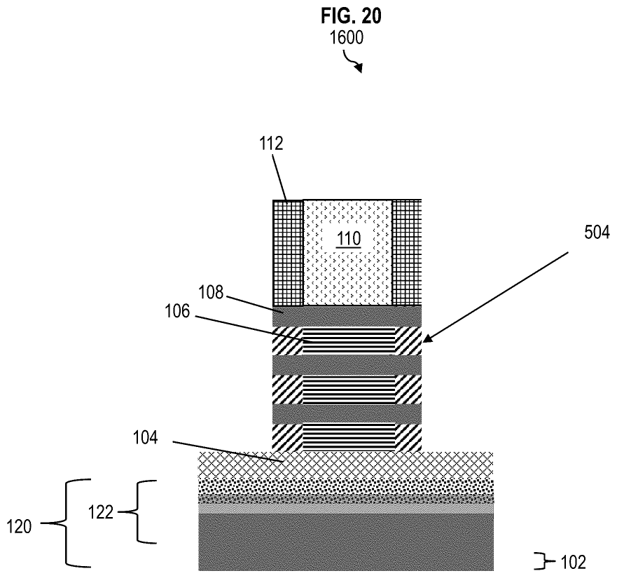

FIG. 20 depicts the IC 1600 after the inner spacer etch back. An isotropic etch can be utilized to selectively etch the inner spacer material 402 as previously discussed herein, thereby resulting in inner spacers 504 in the cavities 302 (depicted in FIG. 3). A wet etch or a dry etch may be utilized. As an example dry etch, a RIE etch can be utilized. As an example wet etch, a dilute phosphoric acid can be utilized.

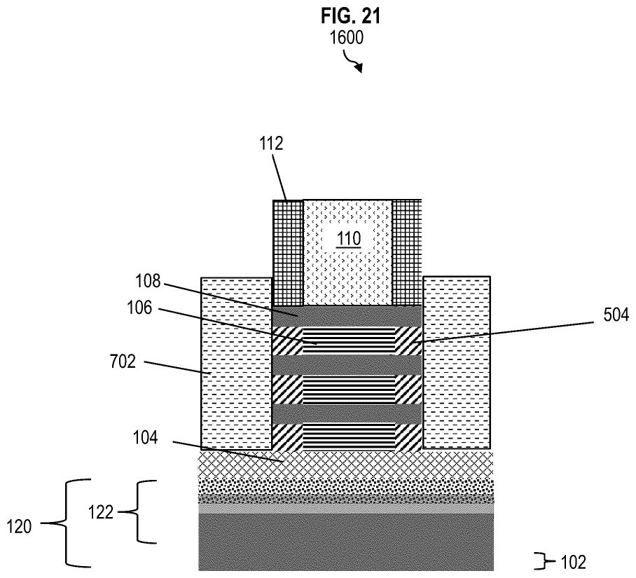

FIG. 21 depicts the IC 1600 after source and drain formation. The epitaxial layers 702 are epitaxially grown from the layers 108. For P-type FETs (PFETs), the epitaxial layers 702 may be doped to be P-type epitaxial material, resulting in P-type source and drain regions. For N-type FETs (NFETs), the epitaxial layers 702 may be doped to be N-type epitaxial material, resulting in N-type source and drain regions. The epitaxial layers 702 sits directly on the first isolation layer 104. In one or more embodiments, the source/drain rejections can be a conductive material or metal that is not epitaxially grown.

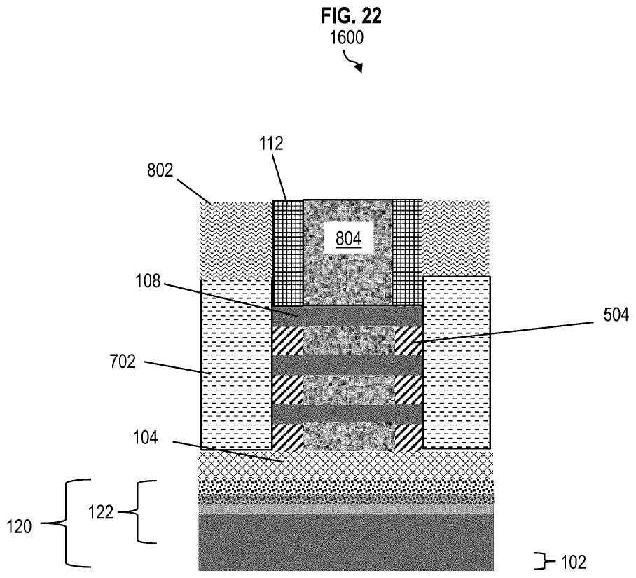

FIG. 22 depicts the IC 1600 after dummy gate removal. The dummy gate 110 is removed, and the sacrificial layers 106 (SiGe) are released. Replacement metal gate (RMG) formation is performed, thereby forming a gate structure 804. The replacement metal gate process is performed to deposit a high-k dielectric material followed by one or more work function material layers to thereby form the gate structure 804. An interlayer dielectric (ILD) material 802 may be formed. The ILD material 802 can be a low-k dielectric material or an ultralow-low k dielectric material. Although not shown, cavities can be formed in the ILD material 802 and a metal can be deposited to fill the cavities, thereby forming the source/drain metal contacts. A portion of the source/drain metal contacts may include silicide, resulting from the interface of the metal material and semiconductor material.

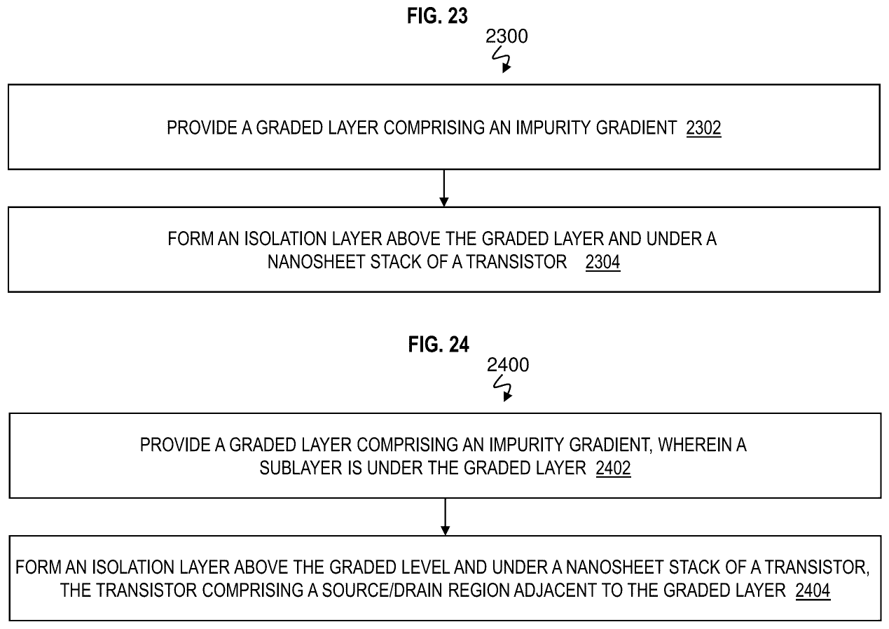

FIG. 23 is a flowchart of a computer-implemented method 2300 for nanosheet transistors with a graded layer under the isolation region according to one or more embodiments. Reference can be made to any figures discussed herein. At block 2302, the method 2300 includes providing a graded layer 122 comprising an impurity gradient. At block 2304, the method 2300 includes forming an isolation layer 104 above the graded layer and under a nanosheet stack 150 of a transistor.

In one or more embodiments, the graded layer 122 comprises a tapered profile, for example, a triangular-like shape. The graded layer 122 comprises a higher concentration of an impurity in the impurity gradient at a region nearest the isolation layer 104 and comprises a lower concentration of the impurity at another region farthest away from the isolation layer 104. For example, the impurity concentration is highest at the area closest to the isolation layer 104 and reduces moving further away from the isolation layer 104. The graded layer 122 comprises a tapered profile in correlation with an impurity concentration in the impurity gradient.

The isolation layer 104 is under a gate region (e.g., gate structure 804) of the transistor. At least a portion of a buried inner spacer layer 502 extends under a gate region (e.g., gate structure 804) of the transistor. A buried inner spacer layer 502 is adjacent to both the isolation layer 104 and the graded layer 122. A buried inner spacer layer 502 is under the isolation layer 104 and comprises a tapered profile. The isolation layer 104 and a buried inner spacer layer 502 are under inner spacers 504, the inner spacers 504 being adjacent to the gate region (e.g., gate structure 804). Another isolation layer 602 is under a source/drain region of the transistor, the another isolation layer 602 being adjacent to the isolation layer 104 and a buried inner spacer layer 502.

FIG. 24 is a flowchart of a computer-implemented method 2400 for nanosheet transistors with a graded layer under the isolation region according to one or more embodiments. Reference can be made to any figures discussed herein.

At block 2402, the method 2400 includes providing a graded layer 122 comprising an impurity gradient, wherein a sublayer 902 is under the graded layer 122 and adjacent to the source/drain region (e.g., epitaxial region 702). At block 2404, the method 2400 includes forming an isolation layer 104 above the graded layer 122 and under a nanosheet stack 150 of a transistor, the transistor comprising a source/drain region (e.g., epitaxial region 702) adjacent to the graded layer 122.

According to one or more embodiments, the sublayer 902 comprises a super steep retrograde well (SSRW) region. The sublayer 902 comprises silicon doped with carbon.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
an isolation layer under a nanosheet stack of a transistor; and
a graded layer under the isolation layer, the graded layer comprising an impurity gradient.

2. The semiconductor structure of claim 1, wherein the graded layer comprises a tapered profile.

3. The semiconductor structure of claim 1, wherein the graded layer comprises a higher concentration of an impurity in the impurity gradient at a region nearest the isolation layer and comprises a lower concentration of the impurity at another region farthest away from the isolation layer.

4. The semiconductor structure of claim 1, wherein the graded layer comprises a tapered profile in correlation with an impurity concentration in the impurity gradient.

5. The semiconductor structure of claim 1, wherein the isolation layer is under a gate region of the transistor.

6. The semiconductor structure of claim 1, wherein at least a portion of a buried inner spacer layer extends under a gate region of the transistor.

7. The semiconductor structure of claim 1, wherein a buried inner spacer layer is adjacent to both the isolation layer and the graded layer.

8. The semiconductor structure of claim 1, wherein a buried inner spacer layer is under the isolation layer and comprises a tapered profile.

9. The semiconductor structure of claim 1, wherein the isolation layer and a buried inner spacer layer are under inner spacers, the inner spacers being adjacent to a gate region.

10. The semiconductor structure of claim 1, wherein another isolation layer is under a source/drain region of the transistor, the another isolation layer being adjacent to the isolation layer and a buried inner spacer layer.

11. A method comprising:
providing a graded layer comprising an impurity gradient; and
forming an isolation layer above the graded layer and under a nanosheet stack of a transistor.

12. The method of claim 11, wherein the graded layer comprises a tapered profile.

13. The method of claim 11, wherein the graded layer comprises a higher concentration of an impurity in the impurity gradient at a region nearest the isolation layer and comprises a lower concentration of the impurity at another region farthest away from the isolation layer.

14. The method of claim 11, wherein the graded layer comprises a tapered profile in correlation with an impurity concentration in the impurity gradient.

15. The method of claim 11, wherein the isolation layer is under a gate region of the transistor.

16. The method of claim 11, wherein at least a portion of a buried inner spacer layer extends under a gate region of the transistor.

17. The method of claim 11, wherein a buried inner spacer layer is adjacent to both the isolation layer and the graded layer.

18. The method of claim 11, wherein a buried inner spacer layer is under the isolation layer and comprises a tapered profile.

19. The method of claim 11, wherein the isolation layer and a buried inner spacer layer are under inner spacers, the inner spacers being adjacent to a gate region.

20. The method of claim 11, wherein another isolation layer is under a source/drain region of the transistor, the another isolation layer being adjacent to the isolation layer and a buried inner spacer layer.

21. A semiconductor structure comprising:
an isolation layer under a nanosheet stack of a transistor, the transistor comprising a source/drain region;
a graded layer under the isolation layer, the graded layer comprising an impurity gradient; and
a sublayer under the graded layer and adjacent to the source/drain region.

22. The semiconductor structure of claim 21, wherein:
the graded layer comprises a tapered profile; and
a buried inner spacer layer is under the isolation layer and adjacent to the graded layer.

23. The semiconductor structure of claim 21, wherein the sublayer comprises a super steep retrograde well (SSRW) region.

24. The semiconductor structure of claim 21, wherein the sublayer comprises silicon doped with carbon.

25. A method comprising:
providing a graded layer comprising an impurity gradient, wherein a sublayer is under the graded layer; and
forming an isolation layer above the graded level and under a nanosheet stack of a transistor, the transistor comprising a source/drain region adjacent to the graded layer.
